(19) United States
(12) Patent Application Publication
(10) Pub. No.: US 2016/0155891 A1
(43) Pub. Date: Jun. 2, 2016

(54) OPTOELECTRONIC COMPONENT AND METHOD FOR THE PRODUCTION THEREOF

(71) Applicant: OSRAM Opto Semiconductors GmbH, Regensburg (DE)

(72) Inventors: Jürgen Moosburger, Regensburg (DE); Ion Stoll, Tegernheim (DE); Thomas Schwarz, Regensburg (DE); Markus Richter, Burglengenfeld (DE); Georg Dirscherl, Tegernheim (DE)

(21) Appl. No.: 14/900,243

(22) PCT Filed: Jun. 25, 2014
(86) PCT No.: PCT/EP2014/063380

§ 371 Date: Dec. 21, 2015

(30) Foreign Application Priority Data
Jun. 26, 2013 (DE) 10 2013 212 247.0

(51) Int. Cl. H01L 33/00; H01L 33/50; H01L 33/60; H01L 33/62; H01L 27/15; H01L 33/54

(52) U.S. Cl. CPC H01L 33/005; H01L 27/15; H01L 33/54; H01L 33/60; H01L 33/62; H01L 33/502; H01L 2933/0033; H01L 2933/0066

(57) ABSTRACT

An optoelectronic component includes an optoelectronic semiconductor chip embedded in a molded body such that an upper side of the optoelectronic semiconductor chip is at least partially not covered by the molded body, wherein a first metallization is arranged on an upper side of the molded body, wherein the first metallization is electrically insulated from the optoelectronic semiconductor chip, and a first material is arranged on the first metallization.

### TECHNICAL FIELD

This disclosure relates to an optoelectronic component and a method of producing an optoelectronic component.

DE 10 2009 036 621 A1 discloses a method of producing an optoelectronic component in which optoelectronic semiconductor chips are arranged on an upper side of a carrier. The optoelectronic semiconductor chips are molded around with a molded body, which covers all the side surfaces of the optoelectronic semiconductor chips. The upper and lower sides of the optoelectronic semiconductor chips preferably remain free. The optoelectronic components can be divided up after the carrier is removed. Contact positions may be provided on the upper and/or lower sides of each semiconductor chip. The molded body may, for example, consist of an epoxide-based molding material.

It could be helpful to provide an improved optoelectronic component and a method of producing an optoelectronic component.

### SUMMARY

We provide an optoelectronic component including an optoelectronic semiconductor chip embedded in a molded body such that an upper side of the optoelectronic semiconductor chip is at least partially not covered by the molded body, wherein a first metallization is arranged on an upper side of the molded body, wherein the first metallization is electrically insulated from the optoelectronic semiconductor chip, and a first material is arranged on the first metallization.

We further provide a method of producing an optoelectronic component including providing an optoelectronic semiconductor chip embedded in a molded body such that an upper side of the optoelectronic semiconductor chip is at least partially not covered by the molded body; applying a first metallization on an upper side of the molded body; and depositing a first material on the first metallization by electrophoretic deposition.

### BRIEF DESCRIPTION OF THE DRAWINGS

FIG. 1 shows a plan view of a molded body of a first optoelectronic component with an embedded optoelectronic semiconductor chip.

FIG. 2 shows a sectional side view of the molded body.

FIG. 3 shows a plan view of the molded body with metallizations arranged thereon.

FIG. 4 shows a sectional side view of the molded body and the metallizations.

FIG. 5 shows a plan view of the molded body with materials deposited over the metallizations.

FIG. 6 shows a sectional side view of the molded body with the metallizations and the materials deposited thereover.

FIG. 7 shows a plan view of a component array.

FIG. 8 shows a plan view of a molded body of a second optoelectronic component.

FIG. 9 shows a sectional side view of the second optoelectronic component.

FIG. 10 shows a plan view of a molded body of a third optoelectronic component.

FIG. 11 shows a sectional side view of the third optoelectronic component.

FIG. 12 shows a sectional side view of a fourth optoelectronic component.

### LIST OF REFERENCES

10 first optoelectronic component
20 second optoelectronic component
30 third optoelectronic component
40 fourth optoelectronic component
100 molded body
101 upper side
102 lower side
200 optoelectronic semiconductor chip
201 upper side
202 lower side
210 upper electrical contact pad
220 lower electrical contact pad
230 mesa
300 through-contact
400 protective chip
500 insulation layer
510 first metallization
515 connecting section
520 second metallization
530 backside metallization
610 mirror layer
615 first material
620 converter layer
625 second material
630 protective layer
640 encapsulation
650 converter element
660 converter element
665 opening
700 component array

### DETAILED DESCRIPTION

Our optoelectronic component comprises an optoelectronic semiconductor chip embedded in a molded body such that an upper side of the optoelectronic semiconductor chip is at least partially not covered by the molded body. A first metallization is arranged on an upper side of the molded body here. The first metallization is electrically insulated from the optoelectronic semiconductor chip. A first material is arranged on the first metallization. The first material may, for example, be arranged on the first metallization by electrophoretic deposition. Since the first metallization action is electrically insulated from the optoelectronic semiconductor chip, the first material is not deposited on the upper side of the optoelectronic semiconductor chip. Advantageously, the molded body, the first metallization and the first material arranged on the first metallization of the optoelectronic component may respectively have a small thickness. In this way, the optoelectronic component advantageously has in total only a very small overall height. The total thickness of the optoelectronic component may be only slightly greater than the thickness of the optoelectronic semiconductor chip. In the lateral direction as well, the optoelectronic component may advantageously have very compact dimensions. A further advantage of the optoelectronic component is that the material arranged on the first metallization can be configured highly densely.

The first material may comprise TiO₂, Al₂O₃, ZrO₂, SiO₂ or HfO₂. In this way, the first material can advantageously have a high optical reflectivity. In this way, the first material arranged on the first metallization on the upper side of the molded body can be used as an optical reflector of the optoelectronic component. Electromagnetic radiation emitted by the optoelectronic semiconductor chip of the optoelectronic component, which is scattered back in the vicinity of the optoelectronic component to the molded body of the optoelectronic component, can then be reflected by the reflector formed by the first material so that absorption of the electromagnetic radiation on the upper side of the molded body of the optoelectronic component is prevented. In this way, the usable fraction of the electromagnetic radiation emitted by the optoelectronic semiconductor chip of the optoelectronic component can advantageously be increased. Since the first material arranged on the first metallization on the upper side of the molded body can form a highly dense layer, a high reflectivity of the first metallization can be obviated. This makes it possible to form the first metallization from an economical and corrosion-stable material, for example, from aluminum.

As an alternative, the first material of the optoelectronic component comprises a colored pigment. In this way, the first material can produce a desired color impression of the optoelectronic component. To this end, the first material may, for example, comprise an inorganic colorant or an oxide or a sulfide of a transition metal.

An element that comprises a luminescent substance, which is configured to convert a wavelength of electromagnetic radiation, may be arranged over the upper side of the optoelectronic semiconductor chip. Advantageously, the element can therefore convert a wavelength of electromagnetic radiation emitted by the optoelectronic semiconductor chip. To this end, the element may absorb electromagnetic radiation with a first wavelength and in turn emit electromagnetic radiation with a second, typically longer, wavelength. The luminescent substance may, for example, be an organic or inorganic luminescent substance. The luminescent substance may also comprise quantum dots.

An electrically conductive through-contact may be embedded in the molded body. Advantageously, the through-contact embedded in the molded body may be used to electrically conductively connect an electrical contact arranged on the upper side of the optoelectronic semiconductor chip to an electrical contact arranged on a rear side of the optoelectronic component. This advantageously makes it possible to electrically contact the optoelectronic semiconductor chip of the optoelectronic component on the rear side of the optoelectronic component. For example, the optoelectronic component may be configured as an SMD component intended for surface mounting.

A protective diode may be embedded in the molded body. Advantageously, the protective diode may be used to protect the optoelectronic semiconductor chip of the optoelectronic component against damage by an electrostatic discharge.

Our method of producing an optoelectronic component comprises the steps of providing an optoelectronic semiconductor chip embedded in a molded body such that an upper side of the optoelectronic semiconductor chip is at least partially not covered by the molded body, applying a first metallization on an upper side of the molded body, and depositing a first material on the first metallization by electrophoretic deposition. Advantageously, the first material arranged on the first metallization of the optoelectronic component which can be obtained by this method may be used as an optical reflector by which a reflectivity of the optoelectronic component is increased. The optical reflector may re-reflect electromagnetic radiation emitted by the optoelectronic semiconductor chip of the optoelectronic component which can be obtained by the method, which is scattered back in the vicinity of the optoelectronic component to the optoelectronic component, and thereby increase the usable fraction of the electromagnetic radiation emitted by the optoelectronic semiconductor chip. Advantageously, the method allows deposition of a highly dense layer of the first material on the first metallization. In this way, the first metallization can be formed from an economical and corrosion-resistant material, the reflectivity of which is only of secondary importance. A particular advantage of the method is that it makes it possible to produce an optoelectronic component with a small total thickness. The molded body may be configured with a thickness substantially corresponding to the thickness of the optoelectronic semiconductor chip. The first metallization and the first material may likewise be applied with very small thicknesses. In the lateral direction as well, the optoelectronic component obtained by the method may be produced with very compact dimensions.

The first metallization may be applied such that the first metallization is electrically insulated from the optoelectronic semiconductor chip. Advantageously, the first material is therefore not deposited on the upper side of the optoelectronic semiconductor chip during deposition of the first material on the first metallization. In this way, the upper side of the optoelectronic semiconductor chip remains transmissive for radiation.

The first material may be deposited in the form of particles having an average size of 200 nm to 10 μm, preferably a size of 400 nm to 800 nm. Advantageously, deposition of the first material in the form of particles with this size makes it possible to produce a highly dense layer of the first material.

The optoelectronic semiconductor chip embedded in the molded body may be provided such that a lower side of the optoelectronic semiconductor chip is at least partially not covered by the molded body. Advantageously, the molded body therefore has a very small thickness essentially corresponding to the thickness of the optoelectronic semiconductor chip. Because the lower side of the optoelectronic semiconductor chip is at least partially not covered by the molded body, the optoelectronic semiconductor chip of the optoelectronic component which can be obtained by the method can be electrically contacted on its lower side. In this way, the optoelectronic component obtained by the method can be configured particularly simply and compactly.

The provision of the optoelectronic semiconductor chip embedded in the molded body may comprise embedding the optoelectronic semiconductor chip in the molded body by a molding process. Embedding the optoelectronic semiconductor chip in the molded body may be carried out, for example, by compression molding or transfer molding, in particular by film assisted transfer molding. Advantageously, the method is therefore easy and economical to carry out and is suitable for mass production.

The method may comprise a further step of applying a second metallization, which is electrically insulated from the first metallization, on the upper side of the molded body. Advantageously, the second metallization may be used to electrically contact the optoelectronic semiconductor chip of the optoelectronic component which can be obtained by the method. Since the second metallization is electrically insulated from the first metallization, the first material is not deposited on the second metallization during the electrophoretic deposition of the first material.

The method may comprise a further step of depositing a second material by electrophoretic deposition. The second material may, in particular, be deposited over the second metallization. Since the second metallization is electrically insulated from the first metallization, the second material is then not deposited over the first metallization during the electrophoretic deposition of the second material.

The second material may comprise a luminescent substance configured to convert a wavelength of electromagnetic radiation. Advantageously, the second material may be used to convert electromagnetic radiation emitted by the optoelectronic semiconductor chip of the optoelectronic component which can be obtained by the method. To this end, the second material may be deposited over the upper side of the optoelectronic semiconductor chip. Deposition of the second material by electrophoretic deposition advantageously makes it possible to produce a highly dense, thin and thermally well connected layer of the second material.

The second material may be deposited in the form of particles which have an average size of 500 nm to 30 μm, preferably 8 μm to 15 μm. Advantageously, deposition of the second material in the form of particles with this size makes it possible to produce a thin and highly dense layer of the second material.

The method may comprise a further step of removing at least a part of the second metallization. Advantageously, parts of the second metallization possibly deposited on the upper side of the optoelectronic semiconductor chip can thereby be removed. In this way, radiation transmissivity of the layers deposited on the upper side of the optoelectronic semiconductor chip is advantageously increased.

The method may comprise a further step of depositing a protective layer over the first material. Advantageously, the protective layer may be used to fix the second material. If a second material has not been deposited, then the protective layer itself may also be used to convert a wavelength of electromagnetic radiation. The protective layer may, for example, comprise silicone or a material of the parylene class.

The protective layer may comprise a luminescent substance configured to convert a wavelength of electromagnetic radiation. The luminescent substance may, for example, be an organic or inorganic luminescent substance. The luminescent substance may also comprise quantum dots. Advantageously, the protective layer of the optoelectronic component which can be obtained by the method may therefore be used to convert a wavelength of electromagnetic radiation emitted by the optoelectronic semiconductor chip of the optoelectronic component.

The method may comprise a further step of arranging a wavelength-converting element over the upper side of the optoelectronic semiconductor chip. The wavelength-converting element may comprise a luminescent substance configured to convert a wavelength of electromagnetic radiation. The luminescent substance may, for example, be an organic or inorganic luminescent substance, and it may also comprise quantum dots. Advantageously, the wavelength-converting element of the optoelectronic component obtained by this method, which is arranged over the upper side of the optoelectronic semiconductor chip, may be used to convert a wavelength of electromagnetic radiation emitted by the optoelectronic semiconductor chip.

The molded body may be provided having a second embedded optoelectronic semiconductor chip. In this case, the first metallization is applied such that a continuous section of the first metallization surrounds the upper side of the first optoelectronic semiconductor chip and an upper side of the second optoelectronic semiconductor chip. Advantageously, the method therefore allows parallel production of a multiplicity of optoelectronic components. Because of the continuous first metallization, the first material may be deposited simultaneously in a common electrophoretic deposition process on all the optoelectronic components. Parallel production of a multiplicity of optoelectronic components in common working operations advantageously reduces production costs of the individual optoelectronic component.

The properties, features and advantages described above and the way in which they are achieved will become more clearly and readily comprehensible in conjunction with the following description of the examples, which will be explained in more detail in connection with the drawings.

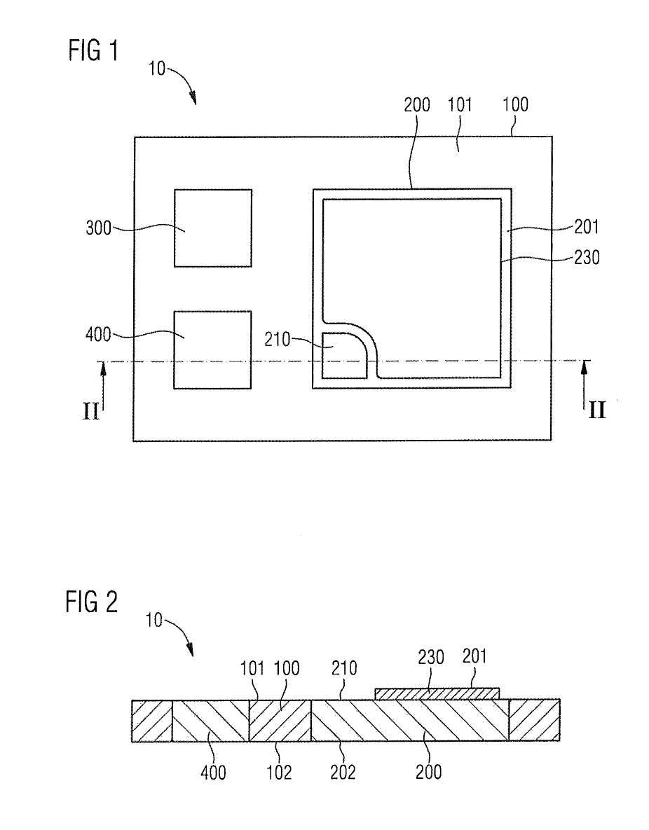

FIG. 1 shows a schematic plan view of a molded body 100 of a first optoelectronic component 10 in an unfinished processing state during production of the first optoelectronic component 10. FIG. 2 shows a sectional side view of the molded body 100 of the first optoelectronic component 10 in the same processing state.

The molded body 100 comprises an electrically insulating plastic material, for example, a plastic material based on an epoxide or on silicone. The material of the molded body 100 may, for example, be black. The molded body 100 was preferably produced by a molding process, for example, by compression molding or transfer molding, in particular, by film assisted transfer molding. The molded body 100 has an upper side 101 and a lower side 102 lying opposite the upper side 101. The upper side 101 and the lower side 102 of the molded body 100 are preferably each configured to be substantially planar.

An optoelectronic semiconductor chip 200 is embedded in the molded body 100. Preferably, the optoelectronic semiconductor chip 200 was already embedded in the material of the molded body 100 during production of the molded body 100. The optoelectronic semiconductor chip 200 has an upper side 201 and a lower side 202 lying opposite the upper side 201. The optoelectronic semiconductor chip 200 is embedded in the molded body 100 such that its lower side 201 is at least partially not covered by the material of the molded body 100. Preferably, the upper side 201 of the optoelectronic semiconductor chip 200 is entirely free and joins approximately flush with the upper side 101 of the molded body 100. The lower side 202 of the optoelectronic semiconductor chip 200 is also preferably at least partially not covered by the molded body 100. In the example of the first optoelectronic component 10 as shown in FIGS. 1 and 2, the lower side 202 of the optoelectronic semiconductor chip 200 is completely free and joins approximately flush with the lower side 102 of the molded body 100.

The optoelectronic semiconductor chip 200 is configured to emit electromagnetic radiation, for example, visible light. In this case, a mesa 230 formed on the upper side 201 of the optoelectronic semiconductor chip 200 forms a radiation emission surface of the optoelectronic semiconductor chip 200. The optoelectronic semiconductor chip 200 may, for example, be a light-emitting diode chip (LED chip). The optoelectronic semiconductor chip 200 may, however, also be a laser chip or another optoelectronic semiconductor chip.

The optoelectronic semiconductor chip 200 has an upper electrical contact pad 210 arranged in a corner region of the upper side 201 of the optoelectronic semiconductor chip 200. Furthermore, the optoelectronic semiconductor chip 200 has a lower electrical contact pad 220 arranged on the lower side 202 of the optoelectronic semiconductor chip 200. An electrical voltage can be applied to the optoelectronic semiconductor chip 200 between the upper electrical contact pad 210 and the lower electrical contact pad 220 to induce emission of electromagnetic radiation by the optoelectronic semiconductor chip 200. It is also possible to arrange both electrical contact pads of the optoelectronic semiconductor chip 200 on the lower side 202 or on the upper side 201 of the optoelectronic semiconductor chip 200. If both electrical contact pads are arranged on the upper side 201 of the optoelectronic semiconductor chip 200, then the lower side 202 of the optoelectronic semiconductor chip 200 may optionally be covered by the material of the molded body 100.

In addition to the optoelectronic semiconductor chip 200, a through-contact 300 is embedded in the molded body 100 of the first optoelectronic component 10. The through-contact 300 extends through the molded body 100 between the upper side 101 and the lower side 102 of the molded body 100 and is respectively accessible on the upper side 101 and the lower side 102 of the molded body 100. The through-contact 300 comprises an electrically conductive material, for example, a suitably doped semiconductor material or a metal. The through-contact 300 was preferably, together with the optoelectronic semiconductor chip 200, already embedded in the material of the molded body 100 during production of the molded body 100. The through-contact 300 may, however, not have been introduced into the molded body 100 until after production of the molded body 100.

The molded body 100 of the first optoelectronic component 10 furthermore has an embedded protective chip 400. The protective chip 400 extends through the molded body 100 between the upper side 101 and the lower side 102 of the molded body 100 and is accessible on the upper side 101 and the lower side 102 of the molded body 100. The protective chip 400 is intended to protect the optoelectronic semiconductor chip 200 against damage by electrostatic discharges. The protective chip 400 may, for example, be configured as a protective diode. The protective chip 400 was preferably, together with the optoelectronic semiconductor chip 200, already embedded in the material of the molded body 100 during production of the molded body 100.

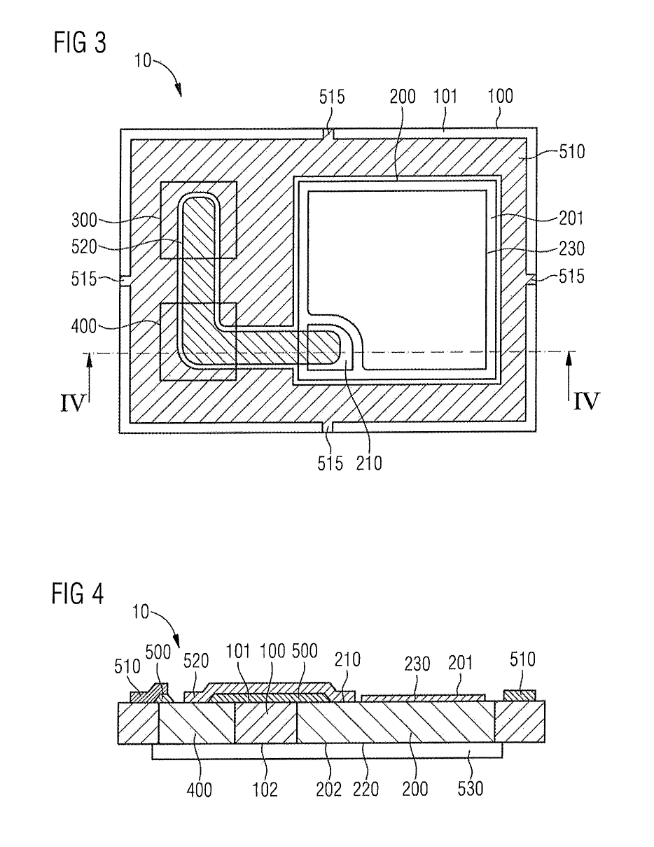

FIG. 3 shows a schematic plan view of the upper side 101 of the molded body 100 of the optoelectronic component 10 in a processing state chronologically following the representation of FIG. 1. FIG. 4 shows a schematic sectional side view of the molded body 100 of the first optoelectronic component 10 in the processing state represented in FIG. 3.

A first metallization 510 and a second metallization 520 have been arranged on the upper side 101 of the molded body 100. The first metallization 510 and the second metallization 520 are arranged in different lateral sections of the upper side 101 of the molded body 100, separated from one another and electrically insulated from one another. The first metallization 510 and the second metallization 520 may, for example, have been arranged on the upper side 101 of the molded body 100 by the methods of planar connection technology.

The first metallization 510 and the second metallization 520 may comprise different materials or the same material. The first metallization 510 preferably comprises a material with a high optical reflectivity, for example, silver or aluminum. The second metallization 520 preferably comprises a highly electrically conductive material. The second metallization 520 may, for example, comprise copper or nickel.

Before the first metallization 510 and the second metallization 520 are arranged on the upper side 101 of the molded body 100, an insulation layer 500 was applied on parts of the upper side 101 of the molded body 100, of the upper side 201 of the optoelectronic semiconductor chip 200 and of the upper sides, exposed on the upper side 101 of the molded body 100, of the through contact 300 and of the protective chip 400. The insulation layer 500 covers parts of the outer edges of the upper side 201 of the optoelectronic semiconductor chip 200 and the upper sides of the through contact 300 and the protective chip 400. In this way, the metallizations 510, 520 arranged over the insulation layer 500 in these regions are electrically insulated from the edges of the optoelectronic semiconductor chip 200, of the through-contact 300 and of the protective chip 400. In this way, short circuits between the first metallization 510 and the second metallization 520 and between the upper electrical contact pad 210 and the lower electrical contact pad 220 of the optoelectronic semiconductor chip 200 are prevented.

The second metallization 520 extends from the upper side of the through-contact 300 over the upper side of the protective chip 400 to the upper electrical contact pad 210 of the optoelectronic semiconductor chip 200, and thereby forms an electrically conductive connection between the through-contact 300, the protective chip 400 and the upper electrical contact pad 210 of the optoelectronic semiconductor chip 200.

The mesa 230 on the upper side 201 of the optoelectronic semiconductor chip 200 is configured to be electrically conductive and, therefore, likewise electrically conductively connects to the second metallization 520. If the mesa 230 of the optoelectronic semiconductor chip 200 were not itself electrically conductive, then the second metallization 520 could also extend over the mesa 230 on the upper side 201 of the optoelectronic semiconductor chip 200.

The first metallization 510 preferably extends essentially over all other sections of the upper side 101 of the molded body 100. The first metallization 510 may also extend partially over the through-contact 300 and the protective chip 400, but is insulated from the through-contact 300 and the protective chip 400 by the insulation layer 500.

A backside metallization 530 has been applied on the lower side 102 of the molded body 100. The backside metallization 530 forms an electrically conductive connection between the lower side, exposed on the lower side 102 of the molded body 100, of the protective chip 400 and the lower electrical contact pad 220 of the optoelectronic semiconductor chip 200.

The protective chip 400 therefore electrically connects in parallel to the optoelectronic semiconductor chip 200 by the backside metallization 530 and the second metallization 520. The parallel connection of the optoelectronic semiconductor chip 200 and of the protective chip 400 is accessible between the lower side, accessible on the lower side 102 of the molded body 100, of the through-contact 300 and the lower electrical contact pad 220 of the optoelectronic semiconductor chip 200.

An electrical voltage can be applied to the optoelectronic semiconductor chip 200 between the lower side of the protective chip 400 and the lower electrical contact pad 220 of the optoelectronic semiconductor chip 200 to induce emission of electromagnetic radiation by the optoelectronic semiconductor chip 200.

The backside metallization 530, connected electrically conductively to the lower electrical contact pad 220 of the optoelectronic semiconductor chip 200, and a metallization arranged on the lower side of the protective chip 400 may be used as solder contacts to electrically contact the first optoelectronic component 10. The first optoelectronic component 10 may, for example, then be used as an SMD component intended for surface mounting, for example, for surface mounting by reflow soldering.

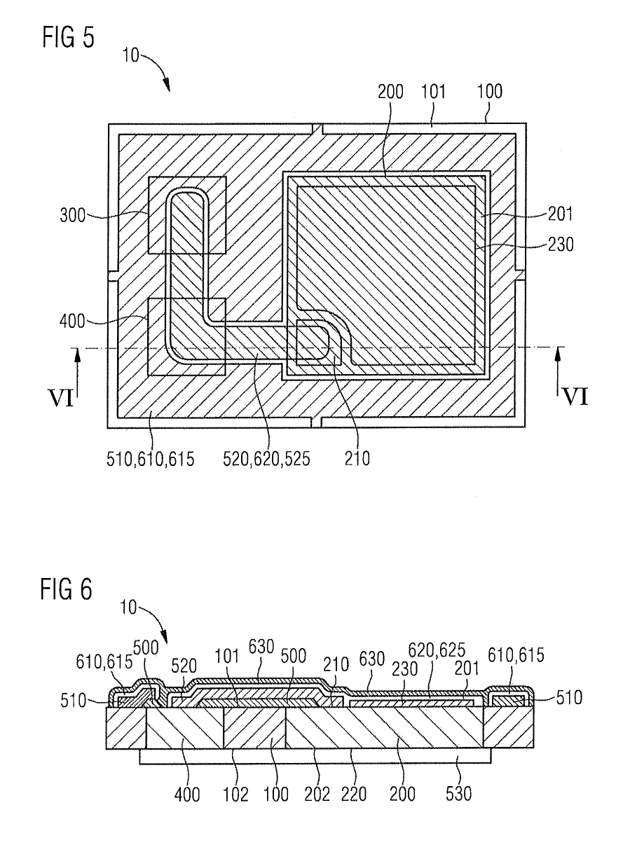

FIG. 5 shows a schematic plan view of the upper side 101 of the molded body 100 of the first optoelectronic component 10 with the metallizations 510, 520 arranged thereon in a processing state chronologically following the representation of FIG. 3. FIG. 6 shows a schematic sectional side view of the molded body 100 of the first optoelectronic component 10 in the same processing state. The production of the first optoelectronic component 10 is essentially completed in the representations of FIGS. 5 and 6.

A mirror layer 610 has been deposited with the first metallization 510 on the upper side 101 of the molded body 100. The mirror layer 610 comprises a first material 615. The first material 615 was arranged over the first metallization 510 by an electrophoretic deposition. The first material 615 has in this case been applied only in the region of the first metallization 510.

The first material 615 of the mirror layer 610 is preferably a highly optically reflective material. For example, the first material 615 of the mirror layer 610 may comprise TiO₂, Al₂O₃, ZrO₂, SiO₂ or HfO₂. The mirror layer 610 therefore forms an optically reflective layer, which can be used to reflect electromagnetic radiation. For example, the mirror layer 610 may re-reflect electromagnetic radiation emitted by the optoelectronic semiconductor chip 200 and reflected back in the vicinity of the first optoelectronic component 10, for example, at a surrounding housing to the upper side 101 of the molded body 100 and, therefore, make it usable. Without the mirror layer 610, the radiation sent back to the upper side 101 of the molded body 100 would be absorbed at the upper side 101 of the molded body 100 and would therefore be lost.

As an alternative, however, the first material 615 of the mirror layer 610 may also comprise a colored pigment. For example, the first material 615 may comprise an inorganic colorant or an oxide or a sulfide of a transition metal. Instead of the mirror layer 610, the first material 615 deposited over the first metallization 510 forms a colored layer which is used to produce a desired color impression of the first optoelectronic component 10.

Preferably, the first material 615 was deposited electrophoretically in the form of particles on the first metallization 510. The particles may preferably have an average size of 200 nm to 10 μm, particularly preferably a particle size of 400 nm to 800 nm. The average size of the particles may, for example, be defined by a d50 value. The diameter of 50 percent by weight of all the particles is less than or equal to the average size.

Between the processing states of the first optoelectronic component 10 as represented in FIGS. 3 and 4 and in FIGS. 5 and 6, a convertor layer 620 was furthermore deposited over the second metallization 520. The convertor layer 620 comprises a second material 625. The second material 625 of the convertor layer 620 was arranged on the second metallization 520 by electrophoretic deposition. The second material 625 of the converter layer 620 has been deposited over the second metallization 520 and over the upper side 201, electrically conductively connected to the second metallization 520, of the optoelectronic semiconductor chip 200. In the other regions of the first optoelectronic component 10, the second material 625 of the converter layer 620 was not deposited.

If the second metallization 520 has extended over the upper side 201 of the optoelectronic semiconductor chip 200, then the part, arranged on the upper side 201 of the optoelectronic semiconductor chip 200, of the second metallization 520 has been removed again after the electrophoretic deposition of the second material 625 of the converter layer 620, without removing the convertor layer 620.

The second material 625 of the converter layer 620 comprises a luminescent configured to convert a wavelength of electromagnetic radiation. To this end, the luminescent substance may absorb electromagnetic radiation with a first wavelength and emit electromagnetic radiation with a second, typically longer, wavelength. The luminescent substance of the second material 620 of the converter layer 620 is intended, in particular, to convert a wavelength of electromagnetic radiation emitted by the optoelectronic semiconductor chip 200 of the first optoelectronic component 10. The second material 625 of the converter layer 620 may, for example, comprise a substance or a substance mixture from the following substance group: Ce³⁺-doped garnets such as YAG:Ce and LuAG, for example, (Y,Lu)₃(Al,Ga)₅O₁₂:Ce³⁺, Eu²⁺-doped nitrides, for example, CaAlSiN₃:Eu²⁺, (Ba,Sr)₂Si₅N₈:Eu²⁺, Eu²⁺-doped sulfides, SIONs, SiAlON, orthosilicates, for example, (Ba,Sr)₂SiO₄:Eu²⁺, chlorosilicates, chlorophosphates, BAM (barium magnesium aluminate:Eu) and/or SCAP, halophosphate.

During electrophoretic deposition of the converter layer 620, the second material 625 is preferably deposited in the form of particles having an average size of 500 nm to 30 μm, particularly preferably 8 μm to 15 μm. The average size of the particles may, for example, be defined by a d50 value. The diameter of 50 percent by weight of all the particles is less than or equal to the average size.

After the electrophoretic deposition of the mirror layer 610 and the electrophoretic deposition of the converter layer 620, a protective layer 630 was applied over the mirror layer 610 and the converter layer 620. The protective layer 630 is used to fix the second material 625 of the converter layer 620, and may also be used to fix the first material 615 of the mirror layer 610. Furthermore, the protective layer 630 may also be used for corrosion protection.

The protective layer 630 preferably comprises an essentially optically transparent material. In particular, the protective layer 630 is preferably transparent for electromagnetic radiation with the wavelength emitted by the optoelectronic semiconductor chip 200 and/or with the wavelength generated by the convertor layer 620. The protective layer 630 may, for example, comprise silicone. Preferably, however, the protective layer 630 comprises a material of the parylene class, in particular type F parylene. The material of the protective layer 630 advantageously has a good crack penetration so that a particularly effective fixing of the second material 625 of the converter layer 620 can be achieved.

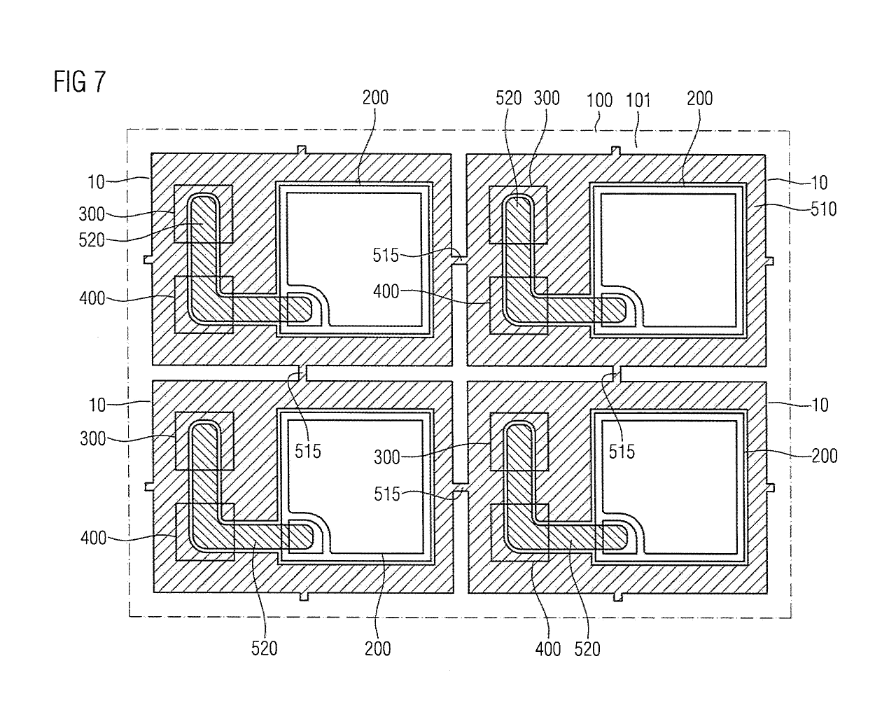

FIG. 7 shows a schematic plan view of a component array 700. The component array 700 comprises a multiplicity of first optoelectronic components 10, on which the production steps explained with the aid of FIGS. 1 to 6 are carried out simultaneously in parallel. This allows parallel production of a plurality of first optoelectronic components 10 in common working operations so that the production costs per individual first optoelectronic component 10 are reduced.

In the component array 700, the molded bodies 100 of the individual first optoelectronic components 10 connect to one another such that they form a common large molded body 100 in which a multiplicity of optoelectronic semiconductor chips 200 and a corresponding multiplicity of through-contacts 300 and protective chips 400 are embedded. The second metallizations 520 of the first optoelectronic components 10 of the component assembly 700 connect to one another by connecting sections 515 such that the first metallizations 510 of the first optoelectronic components 10 are continuous and connected to one another electrically conductively. A continuous section of the first metallizations 510 of the first optoelectronic components 10 of the component assembly 700 therefore encloses the upper sides 201 of all the optoelectronic semiconductor chips 200 of the component array 700.

The electrophoretic deposition of the mirror layer 610 over the first metallization 510 and the electrophoretic deposition of the converter layer 620 over the second metallization 520, as well as the application of the protective layer 630, are carried out together for all the first optoelectronic components 10 of the component array 700. Only then are the molded bodies 100 of the first optoelectronic components 10 of the component assembly 700 separated from one another to divide up the first optoelectronic components 10.

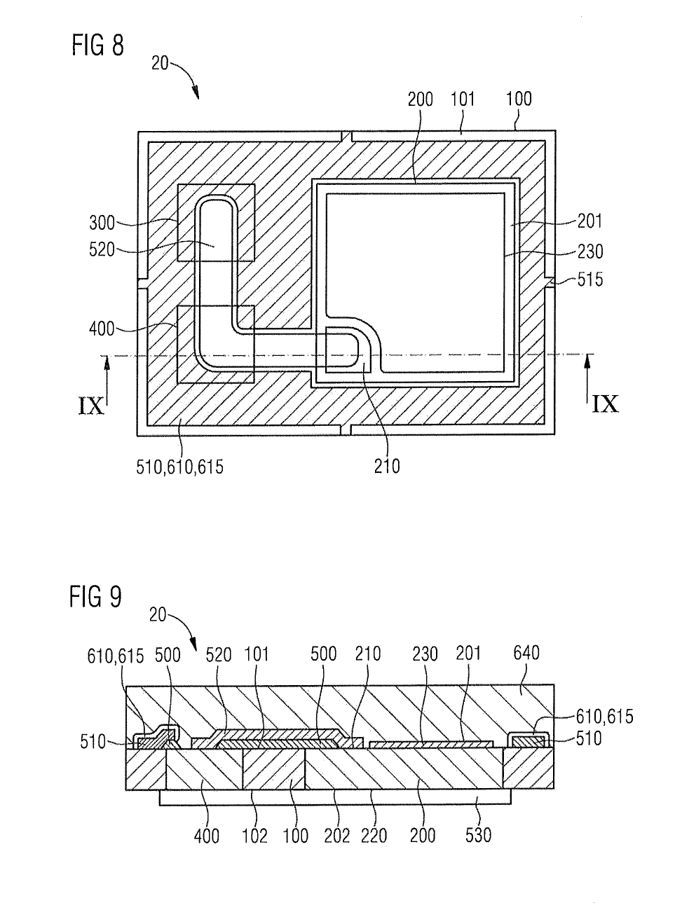

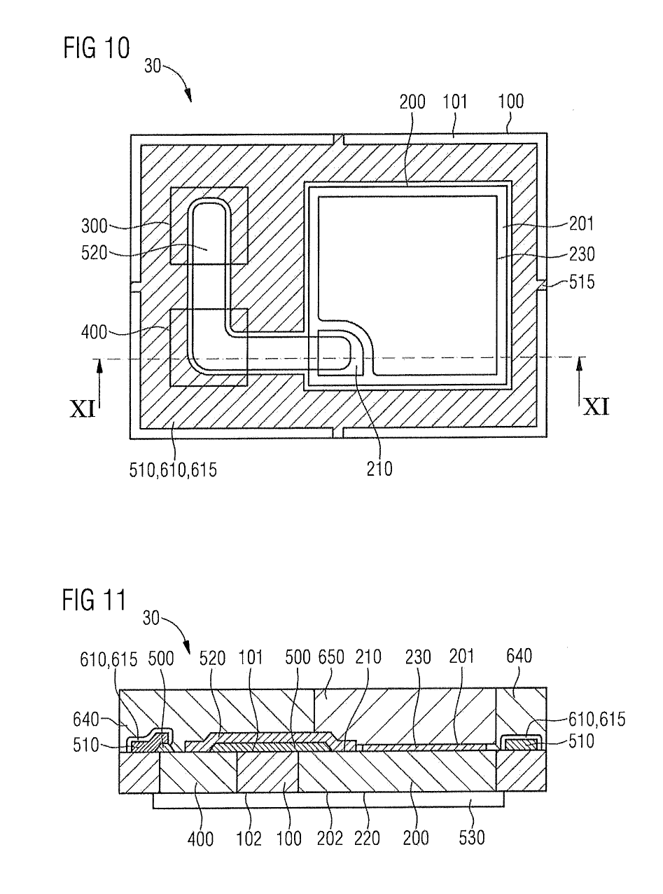

FIG. 8 shows a schematic plan view of a second optoelectronic component 20. FIG. 9 shows a schematic sectional side view of the second optoelectronic component 20. The second optoelectronic component 20 has correspondences with the first optoelectronic component 10. Components of the second optoelectronic component 20 corresponding to components present in the first optoelectronic component 10 are provided with the same references in FIGS. 8 and 9 as in FIGS. 1 to 7 and will not be described again in detail below. In what follows, only the differences between the second optoelectronic component 20 and the first optoelectronic component 10 will be explained.

During production of the second optoelectronic component 20, deposition of the second material 625 of the converter layer 620 is omitted. Also, the protective layer 630 was not applied in the second optoelectronic component 20. Instead, during production of the second optoelectronic component 20 of FIGS. 8 and 9, after the electrophoretic deposition of the first material 615 of the mirror layer 610, an encapsulation 640 was arranged over the upper side 101 of the molded body 100. The encapsulation 640 covers the mirror layer 610, the upper side 201 of the optoelectronic semiconductor chip 200, the second metallization 520 and the remaining sections of the upper side 101 of the molded body 100.

The encapsulation 640 preferably comprises an optically transparent material, in particular a material transparent for electromagnetic radiation emitted by the optoelectronic semiconductor chip 200. The encapsulation 640 may, for example, comprise silicone.

The encapsulation 640 may furthermore comprise an embedded luminescent substance intended to convert electromagnetic radiation emitted by the optoelectronic semiconductor chip 200 of the second optoelectronic component 20 into electromagnetic radiation with a different wavelength. The luminescent substance may be configured like the luminescent substance of the second material 625 of the converter layer 620 of the first optoelectronic component 10.

Instead of the encapsulation 640, in the second optoelectronic component 20 it is also possible for a layer that has been applied by spray coating to be arranged over the upper side 101 of the molded body 100. This layer may also comprise a luminescent substance intended to convert electromagnetic radiation by the optoelectronic semiconductor chip 200 into electromagnetic radiation with a different wavelength.

FIG. 10 shows a schematic plan view of a third optoelectronic component 30. FIG. 11 shows a schematic sectional side view of the third optoelectronic component 30. The third optoelectronic component 30 has correspondences with the first optoelectronic component 10. Components of the third optoelectronic component 30 corresponding to components present in the first optoelectronic component 10 are provided with the same references in FIGS. 10 and 11 as in FIGS. 1 to 7 and will not be described again in detail below. In what follows, only the differences between the third optoelectronic component 30 and the first optoelectronic component 10 will be explained.

During production of the third optoelectronic component 30, the electrophoretic deposition of the second material 625 forming the converter layer 620 over the second metallization 520 was omitted. Also, the protective layer 630 was not provided. Instead, during production of the third optoelectronic component 30, after the electrophoretic deposition of the first material 615 of the mirror layer 610, a converter element 650 was arranged over the upper side 201 of the optoelectronic semiconductor chip 200. Subsequently, the converter element 650 was embedded in an encapsulation 640 which was formed over the upper side 101 of the molded body 100. The encapsulation 640 covers the mirror layer 610, a part of the second metallization 520 and the remaining sections of the upper side 101 of the molded body 100, as well as the side faces of the converter element 650. An upper side of the converter element 650, facing away from the upper side 201 of the optoelectronic semiconductor chip 200, is not covered by the encapsulation 640 and is preferably approximately flush with the encapsulation 640.

The converter element 650 may, for example, comprise silicone or a ceramic material. The converter element 650 comprises an embedded luminescent substance intended to convert electromagnetic radiation emitted by the optoelectronic semiconductor chip 200 into electromagnetic radiation with a different wavelength. The luminescent substance of the converter element 650 may correspond to the luminescent substance of the converter layer 620 of the first optoelectronic component 10.

The encapsulation 640 preferably comprises an optically transparent material. For example, the encapsulation 640 may comprise silicone.

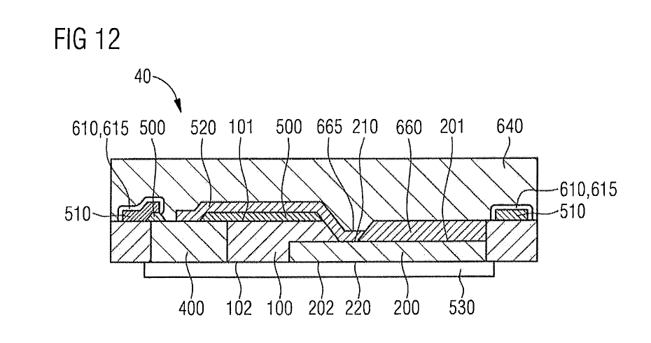

FIG. 12 shows a schematic sectional side view of a fourth optoelectronic component 40. The fourth optoelectronic component 40 has correspondences with the first optoelectronic component 10. Components of the fourth optoelectronic component 40 corresponding to components present in the first optoelectronic component 10 are provided with the same references in FIG. 12 as in FIGS. 1 to 7 and will not be explained again in detail below. In what follows, only the differences between the fourth optoelectronic component 40 and the first optoelectronic component 10 will be described.

In the fourth optoelectronic component 40, a converter element 660 is arranged over the upper side 201 of the optoelectronic semiconductor chip 200. The converter element 660 was already arranged on the upper side 201 of the optoelectronic semiconductor chip 200 before the optoelectronic semiconductor chip 200 was embedded in the molded body 100. Subsequently, the optoelectronic semiconductor chip 200 and the converter element 660 arranged on the upper side 201 of the optoelectronic semiconductor chip 200 were embedded together in the molded body. An upper side of the converter element 660, facing away from the optoelectronic semiconductor chip 200, is flush with the upper side 101 of the molded body 100. The lower side 202 of the optoelectronic semiconductor chip 200 is flush with the lower side 102 of the molded body 100.

The converter element 660 preferably does not cover the upper electrical contact pad 210 arranged on the upper side 201 of the optoelectronic semiconductor chip 200. During embedding of the optoelectronic semiconductor chip 200 and the converter element 660 in the molded body 100, the upper electrical contact pad 210 of the optoelectronic semiconductor chip 200 may therefore have been covered by the material of the molded body 100. In this case, the upper electrical contact pad 210 of the optoelectronic semiconductor chip 200 was exposed by partially removing the material of the molded body 100, for example, by a laser, after embedding of the optoelectronic semiconductor chip 200 and the converter element 660 in the molded body 100. An opening 665 has thereby been applied in the molded body 100 here.

The second metallization 520 applied in a subsequent processing step extends through the opening 665 applied in the molded body 100 to the upper electrical contact pad 210 of the optoelectronic semiconductor chip 200 and, therefore, forms an electrically conductive connection between the upper electrical contact pad 210 of the optoelectronic semiconductor chip 200, the protective chip 400 and the through-contact 300.

During further processing of the fourth optoelectronic component 40, the mirror layer 610 was applied by electrophoretic deposition of the first material 615 over the first metallization 510. The step of depositing the second material 625 of the converter layer 620, carried out to produce the first optoelectronic component 10, is omitted in the production of the fourth optoelectronic component 40. Application of the protective layer 630 is also omitted in production of the fourth optoelectronic component 40. Instead, an encapsulation 640 consisting of optically transparent material has been arranged over the upper side 101 of the molded body 100. The encapsulation 640 covers the mirror layer 610, the converter element 660, the second metallization 520 and the remaining sections of the upper side 101 of the molded body 100. The encapsulation 640 may, for example, again comprise silicone.

Our components and methods have been illustrated and described in detail with the aid of the preferred examples. Nevertheless, this disclosure is not restricted to the examples disclosed. Rather, other variants may be derived therefrom by those skilled in the art without departing from the protective scope of the disclosure or the appended claims.

This application claims priority of DE 10 2013 212 247.0, the disclosure of which is incorporated herein by reference.

1-19. (canceled)

20. An optoelectronic component comprising an optoelectronic semiconductor chip embedded in a molded body such that an upper side of the optoelectronic semiconductor chip is at least partially not covered by the molded body,
wherein a first metallization is arranged on an upper side of the molded body,
wherein the first metallization is electrically insulated from the optoelectronic semiconductor chip, and
a first material is arranged on the first metallization.

21. The optoelectronic component as claimed in claim 20, wherein the first material comprises TiO₂, Al₂O₃, ZrO₂, SiO₂, HfO₂ and/or a colored pigment.

22. The optoelectronic component as claimed in claim 20, wherein an element that comprises a luminescent substance configured to convert a wavelength of electromagnetic radiation is arranged over the upper side of the optoelectronic semiconductor chip.

23. The optoelectronic component as claimed in claim 20, wherein an electrically conductive through-contact is embedded in the molded body.

24. The optoelectronic component as claimed in claim 20, wherein a protective diode is embedded in the molded body.

25. A method of producing an optoelectronic component comprising:
providing an optoelectronic semiconductor chip embedded in a molded body such that an upper side of the optoelectronic semiconductor chip is at least partially not covered by the molded body;
applying a first metallization on an upper side of the molded body; and
depositing a first material on the first metallization by electrophoretic deposition.

26. The method as claimed in claim 25, wherein the first metallization is applied such that the first metallization is electrically insulated from the optoelectronic semiconductor chip.

27. The method as claimed in claim 25, wherein the first material is deposited in the form of particles which have an average size of 200 nm to 10 μm.

28. The method as claimed in claim 25, wherein the optoelectronic semiconductor chip embedded in the molded body is provided such that a lower side of the optoelectronic semiconductor chip is at least partially not covered by the molded body.

29. The method as claimed in claim 25, wherein provision of the optoelectronic semiconductor chip embedded in the molded body comprises embedding the optoelectronic semiconductor chip in the molded body by a molding process.

30. The method as claimed in claim 25, further comprising applying a second metallization electrically insulated from the first metallization on the upper side of the molded body.

31. The method as claimed in claim 25, further comprising depositing a second material by electrophoretic deposition.

32. The method as claimed in claim 31, wherein the second material comprises a luminescent substance configured to convert a wavelength of electromagnetic radiation.

33. The method as claimed in claim 31, wherein the second material is deposited in the form of particles having an average size of 500 nm to 30 μm.

34. The method as claimed in claim 30, further comprising removing at least a part of the second metallization.

35. The method as claimed in claim 25, further comprising depositing a protective layer over the first material.

36. The method as claimed in claim 35, wherein the protective layer comprises a luminescent substance configured to convert a wavelength of electromagnetic radiation.

37. The method as claimed in claim 25, further comprising arranging a wavelength-converting element over the upper side of the optoelectronic semiconductor chip.

38. The method as claimed in claim 25, wherein the molded body is provided having a second embedded optoelectronic semiconductor chip, and
the first metallization is applied such that a continuous section of the first metallization surrounds the upper side of the first optoelectronic semiconductor chip and an upper side of the second optoelectronic semiconductor chip.

39. The method as claimed in claim 31, further comprising removing at least a part of the second metallization.
